(19) United States
(12) Patent Application Publication
(10) Pub. No.: US 2004/0070080 A1
(43) Pub. Date: Apr. 15, 2004

(54) Low cost, high performance flip chip package structure

(75) Inventor: Rajendra D. Pendse, Fremont, CA (US)

Correspondence Address: HAYNES BEFFEL & WOLFELD LLP, P O BOX 366, HALF MOON BAY, CA, 94019, US

(73) Assignee: ChipPAC, Inc, Fremont, CA (US)

(21) Appl. No.: 10/619,381

(22) Filed: Jul. 14, 2003

Related U.S. Application Data
(63) Continuation-in-part of application No. 10/084,787, filed on Feb. 25, 2002.
(60) Provisional application No. 60/272,236, filed on Feb. 27, 2001.

(51) Int. Cl. H01L 23/52

(52) U.S. Cl. 257/778

(57) ABSTRACT

A chip scale integrated circuit chip package includes a die mounted by flip chip interconnection to a package substrate. The package substrate is a laminate including a dielectric layer having a single conductive trace layer on a first surface thereof (the “circuit side” of the substrate) and an active ground plane overlying a second surface thereof (the “dielectric side” of the substrate), wherein the die is mounted on the circuit side of the dielectric layer, the ground plane is electrically connected to ground sites at the first surface of the dielectric layer through openings in the dielectric layer, and wherein second level interconnects are on the circuit side of the dielectric layer. Also, methods for making the package include providing a substrate that includes a laminate including a dielectric layer having a single conductive trace layer on a first surface thereof (the “circuit side” of the substrate) and an active ground plane overlying a second surface thereof (the “dielectric side” of the substrate); affixing a die onto the circuit side of the substrate and forming thereon a flip chip interconnection; filling the vias with an electrically conductive material; applying a ground plane material onto the dielectric side of the substrate; and curing the electrically conductive fill material to form electrical connection between the ground plane and ground sites on the conductive trace layer.

### CROSS REFERENCE TO RELATED APPLICATIONS

This application is a Continuation-In-Part of U.S. application Ser. No. 10/084,787, filed Feb. 25, 2002, which claims the benefit of U.S. Provisional Application No. 60/272,236, filed Feb. 27, 2001, each of which is hereby incorporated by reference in its entirety.

### BACKGROUND

This invention relates to semiconductor device packaging.

Chip packages for housing integrated circuit chips are in increasing demand in applications such as hand-held or portable electronics and in miniaturized storage devices such as disk drives. There is an increasing demand for integrated circuit components having high pin count and low electrical parasitics. In many applications there is a need for such packages to operate at very high frequencies, typically in excess of 1 GHz, to fulfill the needs of analog or RF devices and of fast memories used in cellular phones.

So-called “chip scale packages” are in common use in such applications. Chip scale packages conventionally employ wire bonding as the means for interconnection between the integrated circuit die and the substrate. It is desirable to minimize the thickness of chip scale packages, to the extent practicable. Chip scale packages with wire bond interconnect having an overall package height in the range of 0.6-0.8 mm have been produced.

Further reduction of package thickness is increasingly difficult, owing primarily to two factors. First, wire bonding interconnection employs wire loops of finite height (imposing lower limits on size in the “Z” direction) and span (imposing lower limits on size in the “X” and “Y” directions), running from bond pads at the upper surface of the die, up and then across and down to bond sites on the upper surface of the substrate onto which the die is attached. The loops are then enclosed with a protective encapsulating material. The wire loops and encapsulation typically contribute about 0.2-0.4 mm to the package thickness. Second, as these packages are made thinner, the “second level interconnections” between the package and the printed circuit board are less reliable. In particular, second level interconnections that lie under the “shadow” of the die are most adversely affected.

Moreover, improvement of electrical performance presents significant challenges, for at least two reasons. First, it is difficult to reduce the signal path length, because the wire bonds themselves typically have a length about 1.0 mm. Second, the structure of the package necessitates “wrap-around” routing of conductive traces; that is, the traces have to fan outward to vias, and then run back inward to the solder ball locations.

So-called “flip-chip” packaging can provide significant improvements in electrical performance and reliability in significantly smaller packages, and to meet the demand for package structures that provide for further package miniaturization and improved high-speed operation, the industry has begun to migrate from wire bonding to flip chip interconnection in packages that house high performance devices.

However, there are barriers, making migration from wire bond packaging to flip chip packaging commercially impractical or technically difficult. At present, flip chip packaging imposes a significant premium in price as compared with conventional wire bond packaging; this economic barrier may be expected to disappear as flip chip packages come into more common use.

Moreover, significant technical challenges are presented by the so-called “netlist inversion” effect, which inherently arises when a package component designed for wire bonding is packaged in a conventional flip chip configuration. The netlist inversion effect is discussed in detail with reference to FIGS. 1 and 2, below.

### SUMMARY

According to the invention, a chip package construct employs flip chip interconnection between the die and the package substrate, yet has an uncomplicated design that avoids the netlist inversion problem. The package structure provides high electrical performance yet is made less costly than conventional flip chip packages and cost competitive with wire binding packaging. These advantages are achieved according to the invention by employing for the package substrate a laminate of a dielectric layer and a single conductive layer for the electrical traces. The electrical traces are carried on the “underside” of the substrate, on which the second level interconnects are formed. And, particularly, the die is also mounted on the underside of the package substrate and connected by flip chip interconnection to sites on the electrical traces.

Accordingly, in one general aspect the invention features a chip scale integrated circuit chip package including a die mounted by flip chip interconnection to a package substrate. The package substrate is a laminate (in some embodiments a single metal layer laminate) including a conductive trace layer on a first surface (the “circuit side”) of a dielectric layer. The laminate may alternatively be a tape or film. Overlying a second surface (the “dielectric side”) of the dielectric layer is an active ground plane. The ground plane is electrically connected to ground sites at the circuit side of the dielectric layer through openings in the dielectric layer. Second level interconnects are formed on the circuit side of the dielectric layer, and the die is mounted on the circuit side of the dielectric layer.

In some embodiments the openings in the dielectric layer are filled with an electrically conductive material such as a solder, a conductive ink, or metal-filled (for example silver-filled) epoxy; a silver-filled epoxy may be particularly useful in some embodiments.

In some embodiments an electrically conductive film overlying the dielectric side of the dielectric layer constitutes the ground plane. In some embodiments the electrically conductive film and the electrically conductive fill material are substantially the same material.

In some embodiments the ground plane is formed of a material other than the material of the electrically conductive fill material. In some such embodiments the ground plane is disposed directly upon the surface of the dielectric layer on the dielectric side; in other such embodiments the ground plane is disposed upon a conductive film formed over the dielectric side of the dielectric layer; in still other such embodiments the ground plane is disposed upon an adhesive layer, such as an electrically insulating adhesive layer, formed over the dielectric side of the dielectric layer. The ground plane may be a metal sheet, which may alternatively be a foil or a film. Suitable materials for ground planes in such embodiments include metals such as aluminum, nickel, or copper; a copper ground plane may be particularly useful in some embodiments.

In some embodiments the die is provided with interconnection bumps affixed to an arrangement of connection sites in a first surface (the “interconnect face”) of the die, and the flip chip interconnection is made by apposing the interconnect face of the die with the circuit side of the package substrate and bringing the interconnect bumps into contact with a complementary arrangement of interconnect sites on the conductive trace layer under conditions that promote bonding of the bumps on the interconnect sites.

According to the invention, the interconnect bumps provide a thin gap between the die and the substrate, and this gap may be at least partly filled with a die attach material (such as a die attach epoxy). The combined thickness of the die and the gap is less than the gap provided by the solder ball interconnections between the substrate and the printed circuit board, so that the effective die thickness is accommodated within the second level interconnect gap, and contributes nothing to the overall package thickness (“Z” direction miniaturization).

Moreover, because according to the invention there are no wire bonds connecting this first die to the substrate, the need to accommodate a wire bond span is eliminated, permitting miniaturization in the “X” and “Y” directions as well.

In some embodiments the connection of the interconnect bumps and the pads is a solid state connection, made by applying heat and mechanical force to deform the bumps against the pads without melting either mating surface (thermocompression bonding). Such solid state bonds can provide for finer interconnect geometries than can be obtained using melt-bond connection.

In some embodiments the die is attached at about the center of the substrate, and the solder balls for the second level interconnections are located nearer the periphery of the substrate.

In such embodiments there are no second level connection solder balls in the shadow of the die, so that the second level interconnect reliability can be superior to that of conventional chip scale packages in which there are solder balls under the shadow of the die.

In some embodiments the electrical traces are formed within an interconnect layer in the first surface of the package substrate, and the traces fan outward from the interconnect pads to the solder ball attachment sites.

In such embodiments the signal path is minimized by significant reduction of total trace lengths, both by elimination of wire bonds and by elimination of wraparound routing of traces.

In some such embodiments a ground plane is optionally provided on the second surface of the substrate, and connected to the second level interconnect balls and/or to the interconnect traces through one or more vias in the substrate. Such a ground plane need not be provided with any “keep out” areas, and can be an uninterrupted ground plane structure over the entire second surface. Such a ground plane configuration can provide superior electrical performance, approaching that of micro strip transmission lines.

In some embodiments at least some of the traces are constructed as coplanar waveguides, in which ground lines are formed to run alongside the signal line on a planar dielectric material.

In another general aspect the invention features a method for manufacturing an integrated circuit chip package, by providing a substrate including a dielectric layer having first and second surfaces and a patterned electrically conductive film on the first surface (the side of the substrate having the patterned conductive film being a “circuit side” of the substrate, and the side of the substrate having the second surface being the “dielectric side” of the substrate), with vias through the dielectric layer opening on the second surface; affixing a semiconductor die onto the circuit side of the substrate by flip chip interconnect; applying an electrically conductive material (such as an electrically conductive adhesive or a conductive ink) onto the dielectric side of the substrate, filling the vias and covering at least a portion of the dielectric side of the substrate; and curing the electrically conductive material. The cured electrically conductive material serves as a ground plane, connecting portions of the patterned electrically conductive film on the substrate by way of the vias.

In some embodiments of the method, the substrate is a single metal layer tape substrate, and the method further includes supporting the tape on a stage with at least one side of the substrate exposed for subsequent treatment.

Solder balls for connection of the package to, for example, a printed circuit such as a motherboard can be affixed onto the circuit side of the substrate following the adhesive cure, or at an earlier time in the process.

In some embodiments of the method the die is provided with interconnection bumps affixed to an arrangement of connection sites in a first surface of the die, and the flip chip interconnection is made by apposing the interconnect face of the die with interconnect sites on the circuit side of the substrate and bringing the interconnect bumps into contact with a complementary arrangement of interconnect sites on the patterned conductive film under conditions of pressure and temperature that promote bonding of the bumps on the interconnect sites without melting the material of the bumps or of the interconnect sites on the conductive trace layer.

In some embodiments the method further includes applying a metal (such as, for example, copper or aluminum) sheet (which may, alternatively, be a metal film or foil) onto the exposed surface of the adhesive; in some such embodiments the metal sheet is applied prior to curing the electrically conductive adhesive, so that curing the adhesive affixes the metal sheet onto the dielectric side of the substrate. The metal sheet can serve as a heat spreader.

In another general aspect the invention features a method for manufacturing an integrated circuit chip package, by providing a substrate including a dielectric layer having first and second surfaces, and having an electrically insulating adhesive layer on the second surface and a patterned electrically conductive layer on the first surface (the side of the substrate having the patterned conductive layer being a “circuit side” of the substrate, and the side of the substrate having the adhesive layer being the “dielectric side” of the substrate), with vias, through the insulating adhesive layer and the dielectric layer opening on the exposed surface of the insulating adhesive layer; affixing a semiconductor die onto the circuit side of the substrate by flip chip interconnect; filling the vias with an electrically conductive material (such as a solder paste or an electrically conductive adhesive or conductive ink); applying an electrically conductive layer (such as a curable conductive adhesive or a metal sheet) onto the exposed surface of the electrically insulating material, the electrically conductive layer making electrical contact with the electrically conductive material in the vias (and thereby with selected traces in the patterned electrically conductive layer) and covering at least a portion of the dielectric side of the substrate; and curing the electrically insulating material.

### BRIEF DESCRIPTION OF THE DRAWINGS

FIG. 1 is a diagrammatic sketch in a sectional view of a conventional chip package having wire bond interconnection.

FIG. 2 is a diagrammatic sketch in a sectional view of a conventional flip chip package.

FIG. 3 is a diagrammatic sketch in a sectional view of an embodiment of a high performance flip chip package according to the invention.

FIG. 4 is a diagrammatic sketch in a sectional view of another embodiment of a high performance flip chip package according to the invention.

FIG. 5 is a diagrammatic sketch in a sectional view of yet another embodiment of a high performance flip chip package according to the invention.

FIG. 6 is a flow diagram showing an embodiment of a method according to the invention for making a package as in FIG. 3.

FIG. 7 is a flow diagram showing an embodiment of a method according to the invention for making a package as in FIG. 4.

FIG. 8 is a flow diagram showing an embodiment of a method according to the invention for making a package as in FIG. 5.

### DETAILED DESCRIPTION

The invention will now be described in further detail by reference to the drawings, which illustrate alternative embodiments of the invention. The drawings are diagrammatic, showing features of the invention and their relation to other features and structures, and are not made to scale. For improved clarity of presentation, in the FIGS. illustrating embodiments of the invention, elements corresponding to elements shown in other drawings are not all particularly renumbered, although they are all readily identifiable in all the FIGS. Also for improved clarity, certain details, not necessary to understanding the invention, are not particularly illustrated in the drawings. Terms indicating relative orientation, such as “upper”, “lower”, “top”, “bottom”, “right”, “left” and the like are employed for convenient reference to directions shown in the drawings and, as will be appreciated, any of the embodiments may be deployed in other orientations (upside down, for instance) than as shown in the FIGS.

FIG. 1 shows in a diagrammatic sectional view a conventional wire bonded chip package generally at 10, including a die 14, attached to an “upper” surface 11 of a package substrate 12. The die 14 is electrically connected to the package substrate 12 by way of wire bonds 16, 16′ connected to wire bond pads 15, 15′ on an interconnect face 13 of the die 14 and to interconnect sites in the surface 11 of the substrate 12. The die, the wire bonds, and the “upper” surface 11 of the substrate 12 are enclosed within and protected by a molded plastic encapsulation material 17. A set of second level interconnect balls 18, 18′ are attached to sites on a “lower” surface 19 of the substrate 12 opposite the surface 11 on which the die is attached. For installation of the chip package on a printed circuit board (not shown in the FIGS.), for example, the second level interconnect balls are contacted with corresponding sites on the circuit board. As will be understood, the substrate, referred to as 12 in FIG. 1, includes a number of features not shown in the FIGS.; particularly, for example, electrical connection structures (electrical traces) are conventionally provided at or near the surface 11 for connection with the wire bonds from the die, and vias running through the thickness of the substrate serve to electrically interconnect features on the “top” with the second level interconnects on the “bottom” of the substrate.

It is generally desirable to form the shortest practicable routes between the interconnect sites on the die and the circuitry on the circuit board. That is, referring for example to FIG. 1, the substrate 12 is configured to provide connection between sites near a given edge of the die (e.g., by way of wire bond pads 15 and wire bonds 16, to the left side in FIG. 1) to second level interconnects near a corresponding edge of the package substrate (e.g., to interconnect balls 18, to the left side in FIG. 1); it is generally undesirable (and may be impractical) to make interconnects across the package substrate. Accordingly, it is undesirable or impractical to connect sites near one edge of the die (e.g., by way of wire bond pads 15 and wire bonds 16 near the left edge in FIG. 1) to interconnect balls near the opposite edge of the package substrate (e.g., to interconnect balls 18′ toward the right edge in FIG. 1).

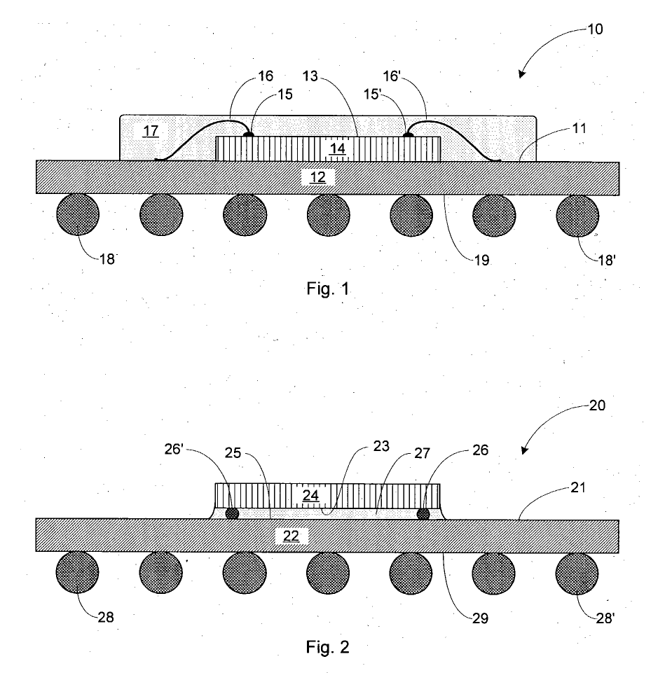

Turning now to FIG. 2, an embodiment of a conventional flip chip package is shown in a diagrammatic sectional view generally at 20. A set of second level interconnect balls 28′, 28 are attached to sites on a “lower” surface 29 of package substrate 22. A die 24 is affixed to a die attach region 25 on the “upper” surface 21 of the package substrate 22 using a die attach material 27, typically a die attach epoxy. In such a flip chip configuration, the die interconnect face 23 is oriented “downwardly” in relation to the package substrate. Interconnection between the die 24 and the substrate 22 is made by way of interconnect bumps 26′, 26 attached to interconnect sites in an arrangement on conductive traces (not shown in the FIGS.) in or near the interconnect face 23 of the die, and the interconnect bumps 26′, 26 are bonded to connection sites in a complementary arrangement (not shown in the FIGS.) on conductive traces in or on the die attach region 25 of the substrate “upper” surface 21. For installation of the chip package on a printed circuit board (not shown in the FIGS.), for example, the second level interconnect balls are contacted with corresponding sites on the circuit board. The substrate 22 in FIG. 2 includes a number of features not shown; particularly, for example, electrical connection structures (electrical traces) are conventionally provided at or near the surface 21 for connection with the die interconnect bumps, and vias running through the thickness of the substrate serve to electrically interconnect features on the “top” with the second level interconnects on the “bottom” of the substrate.

As in the wire bonded package it is generally desirable in the flip chip package to form the shortest practicable routes between the interconnect sites on the die and the circuitry on the circuit board. That is, the substrate 22 is configured to provide connection between sites near a given edge of the die (e.g., by way of bumps 26′, to the left side in FIG. 2) to second level interconnects near a corresponding edge of the package substrate (e.g., to interconnect balls 28, to the left side in FIG. 2), and it is generally undesirable (and may be impractical) to make interconnects across the package substrate. Accordingly, it is undesirable or impractical to connect sites near one edge of the die (e.g., interconnect bumps 26′ near the left in FIG. 2) to interconnect balls near the opposite edge of the package substrate (e.g., to interconnect balls 28′ toward the right in FIG. 2).

The “netlist inversion” problem is illustrated by FIGS. 1 and 2. Particularly, it may be desired to provide a die component 14 in a flip chip package rather than in a wire bonded package, by inverting the die 14 and forming interconnects with the package substrate using interconnect bumps attached to the die in place of the wire bond pads. However, inverting the die not only inverts the up and down orientation of the die faces with respect to the substrate surface (in FIG. 2 die 24 is “upside downward” as compared with die 14 in FIG. 1), but also changes the relative orientation of the die edges with respect to the edges of the substrate (interconnect bumps 26′, toward the left in FIG. 2, correspond to wire bond pads 16′, which are toward the right in FIG. 1). Where a die has been designed for installation in a wire-bonded package on a given circuit, it may be impractical or even impossible to construct a flip chip package, compatible with the given circuit, containing a die made according to the established design.

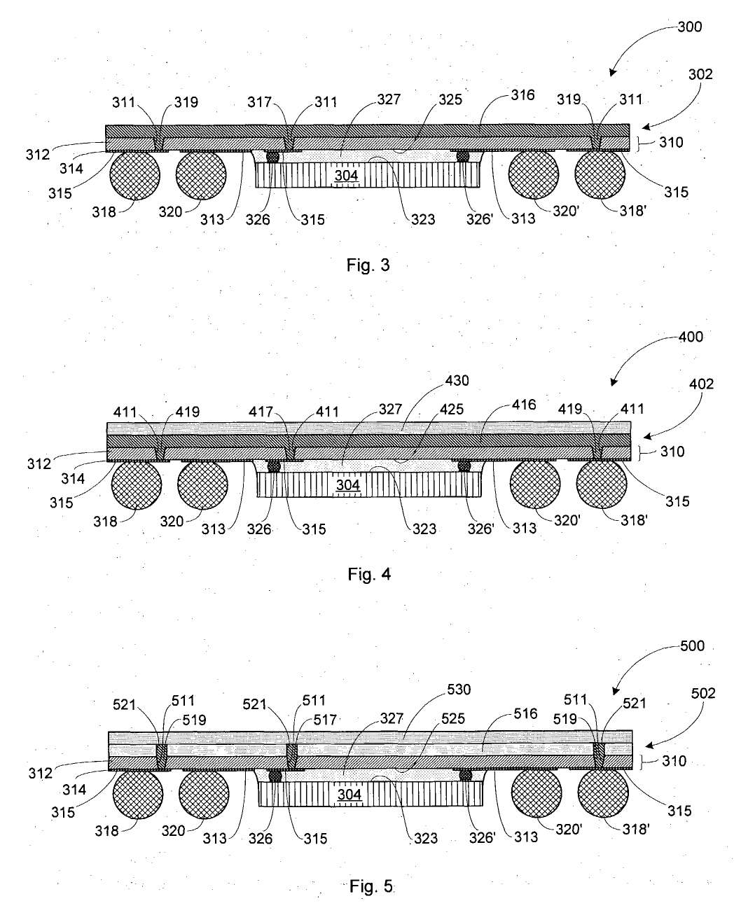

The netlist inversion problem is-avoided in a cost effective package according to the invention, as shown by way of example in FIGS. 3 through 5.

Referring now to FIG. 3, there is shown generally at 300 a flip chip package according to the invention, having a die 304 attached to the “underside” of a package substrate, indicated generally at 302. Package substrate 302 is a laminate or metal tape 310 having a dielectric layer 312 and a single conductive (e.g., metal) trace layer 314. The surface of laminate 310 on which the metal trace layer 314 is carried is the “circuit side”, and the opposite surface of the laminate 310 is the “dielectric side”. Overlying the dielectric side of the dielectric layer 312 is a ground plane 316. Openings 311 through the dielectric layer 312 stop at selected ground sites 315 of the metal trace layer 314. The openings 311 are filled with electrically conductive material 317, 319 to provide electrical connection between the ground plane 316 and ground sites 315 in the metal trace layer 314.

The single conductive layer laminate 310 may be constructed by any of a variety of techniques, including known techniques for manufacturing printed circuit boards, or (for a flexible conductive laminate) methods for manufacturing flexible circuits. Or, the single metal layer laminate 310 may be provided as a metallized tape. Metallized tapes having suitably formed traces may be obtained commercially, for example by arrangement with Sumitomo, or Shindo, or 3M. The openings 311 may be formed in the dielectric layer by any of a variety of techniques, including laser drilling and etching techniques.

The conductive fill material 317, 319 can consist of a so-called “conductive ink” (available by arrangement with DuPont, for example), or a conductive-adhesive such as a metal filled epoxy (available by arrangement with Ablestick, for example), or a solder, or a metal powder slurry (available by arrangement with Alpha Metals, for example). It may be convenient to fill the openings 311 by applying the conductive material in a curable form, such as a paste, and then applying a curing step appropriate to the particular curable conductive material.

As is illustrated in FIG. 3, the ground plane 316 can be formed of the same conductive material as is used to fill the openings 311, and where the conductive material is applied as a curable material, the curable material can be deposited in the openings 311 and as a film over the dielectric surface of the laminate 310, and then cured as appropriate to form the conductive fills 317, 319 and the ground plane 316.

Referring now to any of FIGS. 3-5, the die 304 is affixed to a die attach region 325 (425; 525) on the circuit side of the substrate laminate 310, and is interconnected to the circuitry using flip chip interconnection. That is, the die 304 is provided on an interconnect face 323 with interconnect bumps 326, 326′, and the flip chip interconnection is made by apposing the interconnect face 323 of the die 304 with the die attach region 325 (425; 525) of the circuit side of the substrate laminate 310, and bringing the interconnect bumps into contact with selected interconnect sites on traces 313, 315 of the conductive trace layer 314 under conditions that promote bonding of the bumps on the sites. The interconnect bumps may be formed of any of a variety of metals, including gold, or of metal alloys, including solders. The connection of the interconnect bumps and the interconnect sites may be a “solid state” connection, for example, as solid state bonds can provide for finer interconnect geometries than can be obtained using a melt-bond connection. A solid state interconnection may be completed thermo-mechanically by, for example, concurrently forcing the bonds against the pads and applying sufficient heat to deform the bonds against the pads without melting either the bond material or the pad material. Such solid state interconnect can provide for interconnect geometries in ranges less than about 0.1 mm pitch.

The interconnect bumps provide a thin gap or interconnect standoff between the interconnect face of the die and the substrate, and this gap may be filled, as shown in FIGS. 3-5, with a die attach material such as a die attach epoxy 327.

Second level interconnect solder balls are attached to selected sites in the conductive traces on the circuit side of the substrate, for installation of the package onto, for example, a printed circuit board (not shown in the FIGS.). Particularly, for example, ground balls 318, 318′ are attached to ground sites on selected ground traces 315 of the conductive trace layer 314, in positions that provide for contact with ground potential on the printed circuit board. Input/output balls and power balls 320, 320′ are attached to sites on selected I/O and power traces 313 of the conductive trace layer 314. The ground plane is connected to ground potential on the printed circuit board through ground balls 318, 318′ and ground traces 315 and conductive fill material 319 (419; 519) in selected vias 311 (411; 511), and connection of the die circuitry to ground potential, is completed through interconnects (e.g., 326) that are electrically connected to the ground plane through selected ground traces 315 and conductive fill material 317 (417; 517) in other selected vias 311 (411; 511). Connection of the die circuitry to power and to input and output locations on the printed circuit board is completed through interconnects (e.g., 326′), that are electrically connected through traces 313 to I/O or power balls (e.g., 320′) that are attached in positions that provide for contact with I/O and power locations on the printed circuit.

The configuration according to the invention avoids the netlist problem, because although the die is attached to the package substrate using flip chip interconnection, the die is oriented with its interconnect face upwards with respect to the underlying printed circuit board, so that the X-Y orientation of the die with respect to the printed circuit can be the same as if the die had been attached using wire bonding to the upper side of the package substrate (as shown for illustration in FIG. 1).

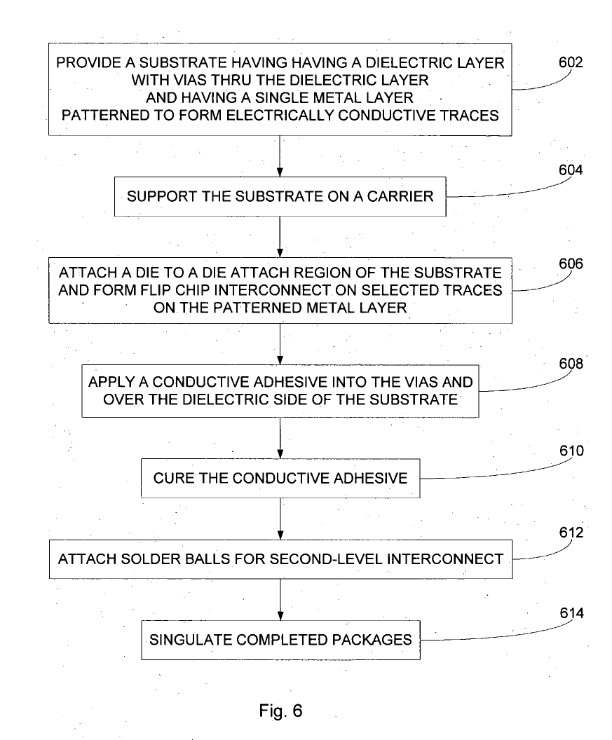

A method for making a package as in FIG. 3 is shown by way of example in FIG. 6. Referring to both FIGS. 3 and 6, in a first step 602 a package substrate 302 is provided, as a laminate or tape 310 having a dielectric layer 312 and a patterned metal trace layer 314, and having vias 311 opening on the dielectric side of the dielectric layer and passing through the dielectric layer to selected ground sites 315 in the metal trace layer. As will be appreciated, the patterning of the metal trace layer and the location of the vias will be designed according to the particular chip configuration and the particular package installation environment, which typically will be a printed circuit board for example. The laminate or tape may preferably be dimensioned, and the metal layer may be patterned, such that a multiple of package substrates may be formed from it, arranged in a row or in an array.

In a step 604 the multiple package substrate 302 is supported on carrier, which may preferably be an open frame supporting the multiple package substrate at the margins, so that both the circuit side and the dielectric side may be exposed for subsequent processing. In a step 606 a die 304 is attached to each of the multiple die attach regions 325 on the circuit side of the multiple package substrate 302 using a die attach epoxy 327, and the flip chip interconnection is made by forming electrical contact of the interconnect bumps 326 and 326′ with interconnect sites of the metal trace layer 314. Typically, the die attach step 606 entails a pick-and-place operation and an interconnect operation. It may be preferred to form the flip chip interconnect by a thermo-mechanical technique, in which a solid-state connection is formed between the interconnect balls on the chip and the sites on the metal traces without melting either the interconnect balls or the sites on the metal traces.

In a step 608 a curable electrically conductive material such as an electrically conductive adhesive is applied on to the dielectric side of the multiple package substrate 302 so as to fill the vias and to form a layer of curable electrically conductive material over the surface of the dielectric layer 312. The curable electrically conductive material may be applied by any of a variety of techniques, such as by printing (e.g., screen printing) or by applying a mass of the material and then leveling it using a doctor blade. Then, in a step 610, the electrically conductive material is cured to form a ground plane 316 and to form electrical connections 317, 319 in the vias 311 between the ground plane and the selected ground sites 315 in the metal trace layer. In a step 612, second-level interconnect solder balls are attached to sites on the metal layer for connection to, for example, a printed circuit board: input/output balls and power balls 320, 320′ are attached to sites on selected I/O and power traces 313, and ground balls 318, 318′ are attached to sites on ground traces 315. A step 614, the completed packages are saw- or punch-singulated. Certain of the steps or operations may be performed in a sequence different from that shown in FIG. 6, as may be convenient for a particular fabrication unit. For example, the die attach operation may be carried out following the operation of applying the curable electrically conductive material. And, for example, the second-level interconnect solder balls may be attached at an earlier point in the process, such as prior to the operation of applying the curable electrically conductive material.

FIG. 4 shows generally at 400 a flip chip package of the invention in an alternative embodiment, having a die 304 attached to the “underside” of a package substrate 402, and having a heat spreader attached to the upper surface of the conductive film overlying the dielectric layer of the substrate. Package substrate 402 is a laminate or metal tape 310 having a dielectric layer 312 and a single conductive (e.g., metal) trace layer 314. The surface of laminate 310 on which the metal trace layer 314 is carried is the “circuit side”, and the opposite surface of the laminate 310 is the “dielectric side”. Overlying the dielectric side of the dielectric layer 312 is a ground plane 416. Openings 411 through the dielectric layer 312 stop at selected ground sites 315 of the metal trace layer 314. The openings 411 are filled with electrically conductive material 417, 419 to provide electrical connection between the ground plane 416 and ground sites 315 in the metal trace layer 314.

The single conductive layer laminate 310 may be constructed by any of a variety of techniques, including known techniques for manufacturing printed circuit boards, or (for a flexible conductive laminate) methods for manufacturing flexible circuits. Or, the single metal layer laminate 310 may be provided as a metallized tape. Metallized tapes having suitably formed traces may be obtained commercially, for example by arrangement with Sumitomo, or Shindo, or 3M. The openings 311 may be formed in the dielectric layer by any of a variety of techniques, including laser drilling and etching techniques.

The conductive fill material 417, 419 can consist of a so-called “conductive ink” (available by arrangement with DuPont, for example), or a conductive adhesive such as a metal filled epoxy (available by arrangement with Ablestick, for example), or a solder, or a metal powder slurry (available by arrangement with Alpha Metals, for example). It may be convenient to fill the openings 411 by applying the conductive material in a curable form, such as a paste, and then applying a curing step appropriate to the particular curable conductive material.

As is illustrated in FIG. 4, the ground plane 416 can be formed of the same conductive material as is used to fill the openings 411, and where the conductive material is applied as a curable material, the curable material can be deposited in the openings 411 and as a film over the dielectric surface of the laminate 310. In such embodiments the heatspreader 430 can be applied onto the exposed (“upper”) surface of the curable conductive material of the ground plane 416, and then the conductive material is cured as appropriate to form the conductive fills 417, 419 and the ground plane 416. As the conductive material of the ground plane cures, the heatspreader 430 becomes affixed onto its “upper” surface.

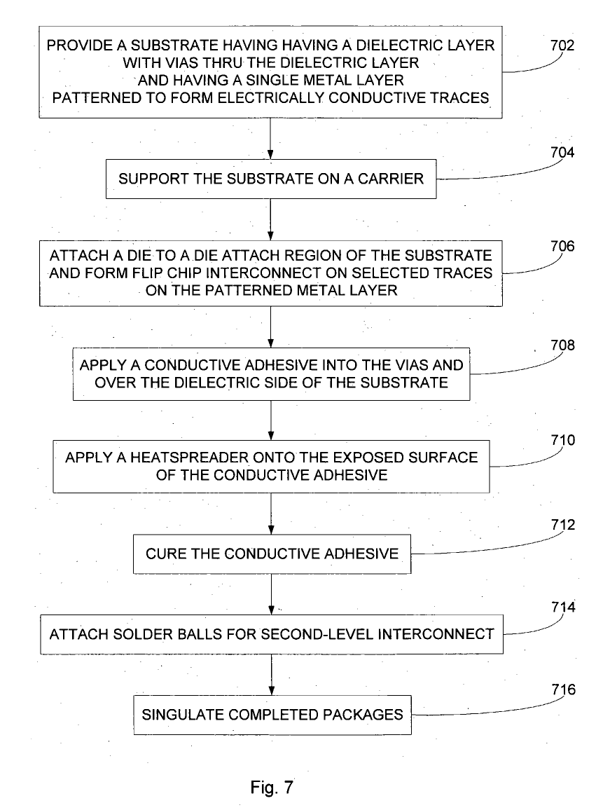

A method for making a package as in FIG. 4 is shown by way of example in FIG. 7. Referring to both FIGS. 4 and 7, in a first step 702 a package substrate 402 is provided, as a laminate or tape 310 having a dielectric layer 312 and a patterned metal trace layer 314, and having vias 411 opening on the dielectric side of the dielectric layer and passing through the dielectric layer to selected ground sites 315 in the metal trace layer. As will be appreciated, the patterning of the metal trace layer and the location of the vias will be designed according to the particular chip configuration and the particular package installation environment, which typically will be a printed circuit board for example. The laminate or tape may preferably be dimensioned, and the metal layer may be patterned, such that a multiple of package substrates may be formed from it, arranged in a row or in an array.

In a step 704 the multiple package substrate 402 is supported on carrier, which may preferably be an open frame supporting the multiple package substrate at the margins, so that both the circuit side and the dielectric side may be exposed for subsequent processing. In a step 706 a die 304 is attached to each of the multiple die attach regions 425 on the circuit side of the multiple package substrate 302 using a die attach epoxy 327, and the flip chip interconnection is made by forming electrical contact of the interconnect bumps 326 and 326′ with interconnect sites of the metal trace layer 314. Typically, the die attach step 706 entails a pick-and-place operation and an interconnect operation. It may be preferred to form the flip chip interconnect by a thermo-mechanical technique, in which a solid-state connection is formed between the interconnect balls on the chip and the sites on the metal traces without melting either the interconnect balls or the sites on the metal traces, as described for example in U.S. application Ser. No. 09/802,375, filed Mar. 9, 2001, which is hereby incorporated by reference.

In a step 708 a curable electrically conductive material such as an electrically conductive adhesive is applied on to the dielectric side of the multiple package substrate 302 so as to fill the vias and to form a layer of curable electrically conductive material over the surface of the dielectric layer 312. The curable electrically conductive material may be applied by any of a variety of techniques, such as by printing (e.g., screen printing) or by applying a mass of the material and then leveling it using a doctor blade. Then, in a step 710, the heatspreader 430 is applied onto the exposed (“upper”) surface of the uncured ground plane material. Then, in a step 712 the electrically conductive material is cured to form the ground plane 416, to form electrical connections 417, 419 in the vias 411 between the ground plane and the selected ground sites 315 in the metal trace layer, and to affix the heatspreader onto the ground plane. In a step 714, second-level interconnect solder balls are attached to sites on the metal layer for connection to, for example, a printed circuit board: input/output balls and power balls 320, 320′ are attached to sites on selected I/O and power traces 313, and ground balls 318, 318′ are attached to sites on ground traces 315. A step 716, the completed packages are saw- or punch-singulated. Certain of the steps or operations may be performed in a sequence different from that shown in FIG. 7, as may be convenient for a particular fabrication unit. For example, the die attach operation may be carried out following the operation of applying the curable electrically conductive material. And, for example, the second-level interconnect solder balls may be attached at an earlier point in the process, such as prior to the operation of applying the curable electrically conductive material.

FIG. 5 shows generally at 500 a flip chip package of the invention in an alternative embodiment, having a die 304 attached to the “underside” of a package substrate 502, and having a heat spreader that additionally functions as a ground plane, affixed using an electrically insulating adhesive over the dielectric layer of the substrate. Such a heat spreader/ground plane may be provided as a more or less continual electrically conductive sheet (for example, a metal such as copper) substantially covering the upper surface of the substrate.

Package substrate 502 is a laminate or metal tape 310 having a dielectric layer 312 and a single conductive (e.g., metal) trace layer 314. The surface of laminate 310 on which the metal trace layer 314 is carried is the “circuit side”, and the opposite surface of the laminate 310 is the “dielectric side”. Overlying the dielectric side of the dielectric layer 312 is an electrically insulating adhesive layer 516. Openings 511 through the dielectric layer 312 and the electrically insulating layer 516 stop at selected ground sites 315 of the metal trace layer 314. Overlying the electrically insulating layer 516 is an electrically conductive layer (or sheet) 530, which acts as a ground plane. The openings 511 are filled with electrically conductive material 517, 519, and the fill material 517, 519 contacts the underside of the ground plane 530 to provide electrical connection between the ground plane 530 and ground sites 315 in the metal trace layer 314.

As in embodiments described above with reference to FIGS. 3 and 4, the single conductive layer laminate 310 in embodiments of FIG. 5 may be constructed by any of a variety of techniques, including known techniques for manufacturing printed circuit boards, or (for a flexible conductive laminate) methods for manufacturing flexible circuits. Or, the single metal layer laminate 310 may be provided as a metallized tape. Metallized tapes having suitably formed traces may be obtained commercially, for example by arrangement with Sumitomo, or Shindo, or 3M. The openings 511 may be formed in the dielectric layer and adhesive layer by any of a variety of techniques, including laser drilling and etching techniques.

Also as in embodiments described above with reference to FIGS. 3 and 4, the conductive fill material 517, 519 can consist of a so-called “conductive ink” (available by arrangement with DuPont, for example), or a conductive adhesive such as a metal filled epoxy (available by arrangement with Ablestick, for example), or a solder, or a metal powder slurry (available by arrangement with Alpha Metals, for example). It may be convenient to fill the openings 511 by applying the conductive material in a curable form, such as a paste, and then applying a curing step appropriate to the particular curable conductive material. It may in such instances be preferable to cure the conductive fill material after the ground plane has been applied, so that during cure good electrical connection is made between the under surface of the ground plane and the fill material.

Or, the ground plane 530 can be formed of a curable conductive material, and may be the same conductive material as is used to fill the openings 511. Where the ground plane is applied as a curable material, the curable material can be deposited in the openings 511 and as a layer over the exposed “upper” surface of the electrically insulating material layer 516. In such embodiments the deposited curable electrically conductive material can be cured to form the conductive fills 517, 519 and the ground plane 530. As may be appreciated, the ground plane 530 in such embodiments can, if it is sufficiently thermally conductive, be effective both as a ground plane and as a heat spreader.

The dimensions of the various features can be selected to minimize the overall thickness of the package. For example, the bump structures and interconnection means can be designed so that the gap between the interconnect face on the die and the die attach surface of the substrate is less than about 0.025 mm. Because the die in this embodiment is carried on the lower surface of the substrate, and because its thickness is accommodated within the gap between the lower surface of the substrate and the underlying integrated circuit, as limited by the size of the second level interconnect balls, the overall package is thinner than a wire bonded package having a similar die and a similar substrate by an amount corresponding to about the thickness of the wire bonded die and its encapsulation, as illustrated for example in FIG. 1. Moreover, because the second level interconnect structures are located near the periphery of the substrate, the second level reliability is superior to that obtainable where there are there are solder balls situated in the shadow of the die.

Advantageously, the conductive traces running from the connection sites in the circuit side of the substrate can according to the invention run directly to assigned solder ball connection sites.

In a typical embodiment for a chip scale package, the thickness of the package substrate is approximately 0.1 mm, the height of the solder balls measured from the substrate surface is approximately 0.3 mm, and the height of the die is approximately 0.18 mm; this gives an overall package height of approximately 0.4 mm. Further reductions in these dimensions are possible, so that overall package heights les than 0.4 mm can be obtained according to the invention.

Moreover, the length of the longest conductive traces can be less than 1.0 mm in an embodiment having two peripherally arranged rows of solder balls at a 0.5 mm pitch. This can provide exceptionally high electrical performance.

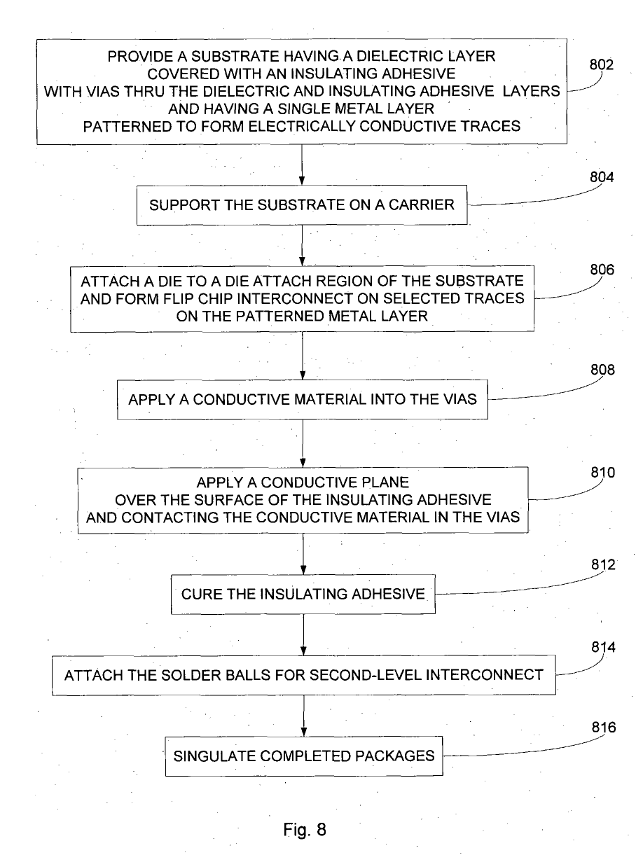

A method for making a package as in FIG. 5 is shown by way of example in FIG. 8. Referring to both FIGS. 5 and 8, in a first step 802 a package substrate 502 is provided, as a laminate or tape 310 having a dielectric layer 312 and a patterned metal trace layer 314, and additionally having an electrically insulating layer 516 over the “upper” surface of the dielectric layer 312. The substrate 502 is provided with vias 511, 521 opening on the “upper” surface of the electrically insulating layer 516, and passing through the electrically insulating layer 516 (vias 521) and the dielectric layer 312 (vias 511) to selected ground sites 315 in the metal trace layer. As will be appreciated, the patterning of the metal trace layer and the location of the vias will be designed according to the particular chip configuration and the particular package installation environment, which typically will be a printed circuit board for example. The laminate or tape may preferably be dimensioned, and the metal layer may be patterned, such that a multiple of package substrates may be formed from it, arranged in a row or in an array.

In a step 804 the multiple package substrate 502 is supported on carrier, which may preferably be an open frame supporting the multiple package substrate at the margins, so that both the circuit side and the dielectric side may be exposed for subsequent processing. In a step 806 a die 304 is attached to each of the multiple die attach regions 525 on the circuit side of the multiple package substrate 302 using a die attach epoxy 327, and the flip chip interconnection is made by forming electrical contact of the interconnect bumps 326 and 326′ with interconnect sites of the metal trace layer 314. Typically, the die attach step 806 entails a pick-and-place operation and an interconnect operation. It may be preferred to form the flip chip interconnect by a thermo-mechanical technique, in which a solid-state connection is formed between the interconnect balls on the chip and the sites on the metal traces without melting either the interconnect balls or the sites on the metal traces.

In a step 808 a curable electrically conductive material such as an electrically conductive adhesive is applied into the vias 511, 521, so as to fill the vias to at least flush with the “upper” surface of the electrically insulating layer 516. The curable electrically conductive material may be applied by any of a variety of techniques, such as by printing (e.g., screen printing) or by applying a mass of the material and then leveling it using a doctor blade. Then, in a step 810, the heatspreader 530 is applied onto the exposed (“upper”) surface of the uncured electrically insulating material. Then, in a step 812 the electrically insulating material is treated to cure and form the insulating layer 516, and also the electrically conductive fill material is treated to cure and form electrical connections 517, 519 in the vias 511, 521 between the ground plane and the selected ground sites 315 in the metal trace layer, and to affix the ground plane/heat spreader 530 onto the electrically insulating layer 516. In a step 814, second-level interconnect solder balls are attached to sites on the metal layer for connection to, for example, a printed circuit board: input/output balls and power balls 320, 320′ are attached to sites on selected I/O and power traces 313, and ground balls 318, 318′ are attached to sites on ground traces 315. In a step 816, the completed packages are saw- or punch-singulated. Certain of the steps or operations may be performed in a sequence different from that shown in FIG. 8, as may be convenient for a particular fabrication unit. For example, the die attach operation may be carried out following the operation of applying the curable electrically conductive material. And, for example, the second-level interconnect solder balls may be attached at an earlier point in the process, such as prior to the operation of applying the curable electrically conductive material. The process for curing the electrically insulating material of layer 516 may be the same as, or different from, the process for curing the electrically conductive fill material of the connections 517, 519; where the process is the same, or where the cure processes are compatible, the cures may be performed concurrently.

Also, as noted above, the ground plane may be applied as a curable electrically conductive material and may be curable by the same process as, or may be the same material as, the fill material in the vias, and in such embodiments the step of curing the electrically conductive material also serves to cure the ground plane. In other embodiments the ground plane is of a different curable material and must be cured in a separate step (which may, if the cure processes are compatible, run concurrently). In still other embodiments the ground plane is a sheet of an electrically conductive material, which may for example include a metal sheet or film such as a copper sheet; in such embodiments the cure of the electrically insulating layer serves to affix the ground plane onto the “upper” surface of the insulating layer.

Other embodiments are within the following claims.

What is claimed is:

1. A chip scale integrated circuit chip package comprising a die mounted by flip chip interconnection to a package substrate, the package substrate being a laminate comprising a dielectric layer having a single conductive trace layer on a first surface thereof and an active ground plane overlying a second surface thereof, wherein the ground plane is electrically connected to ground sites at the first surface of the dielectric layer through openings in the dielectric layer, and wherein second level interconnects are on the first surface of the dielectric layer, and the die is mounted on the first surface of the dielectric layer.

2. The package of claim 1 wherein the openings in the dielectric layer are filled with an electrically conductive material.

3. The package of claim 2 wherein the electrically conductive material comprises a solder.

4. The package of claim 2 wherein the electrically conductive material comprises a conductive ink.

5. The package of claim 2 wherein the electrically conductive material comprises a metal-filled epoxy.

6. The package of claim 5 wherein the electrically conductive material comprises a silver-filled epoxy.

7. The package of claim 1 wherein the ground plane comprises an electrically conductive film overlying the second surface of the dielectric layer.

8. The package of claim 1 wherein the openings in the dielectric layer are filled with an electrically conductive material and the ground plane and the electrically conductive fill material are substantially the same material.

9. The package of claim 1 wherein the openings in the dielectric layer are filled with an electrically conductive material and the ground plane is formed of a material different from the electrically conductive fill material.

10. The package of claim 1 wherein the ground plane is disposed directly upon the surface of the dielectric layer on the dielectric side.

11. The package of claim 1 wherein the ground plane is disposed upon a conductive film formed over the dielectric side of the dielectric layer.

12. The package of claim 1 wherein the ground plane is disposed upon an adhesive layer formed over the dielectric side of the dielectric layer.

13. The package of claim 12 wherein the adhesive layer comprises an electrically insulating adhesive layer.

14. The package of claim1 wherein the ground plane comprises a metal.

15. The package of claim 14 wherein the ground plane comprises aluminum.

16. The package of claim 14 wherein the ground plane comprises nickel.

17. The package of claim 14 wherein the ground plane comprises copper.

18. The package of claim 1 wherein a gap between the die and the substrate is at least partly filled with a die attach material.

19. The package of claim 18 wherein the die attach material comprises an epoxy.

20. The package of claim 1 wherein the die is provided with interconnection bumps affixed to an arrangement of connection sites in a first surface of the die, and the conductive trace layer is provided with a complementary arrangement of interconnect sites, and the flip chip interconnection is a solid state interconnection.

21. The package of claim 1 wherein the die is attached at about the center of the first side of the substrate, and solder balls for second level interconnections are located nearer the periphery of the first side of the substrate.

22. The package of claim 1 wherein the electrical traces are formed within an interconnect layer in the first surface of the package substrate, and the traces fan outward from the interconnect pads to the solder ball attachment sites.

23. The package of claim 1 wherein at least some of the traces are constructed as coplanar waveguides, each comprising ground lines alongside a signal line on a planar dielectric material.

24. A method for manufacturing an integrated circuit chip package, comprising
providing a substrate having a circuit side and a dielectric side, the substrate comprising an electrically insulating layer and a patterned electrically conductive layer, the substrate further including vias through the insulating layer opening on an exposed surface of the insulating layer;
affixing a semiconductor die onto the circuit side of the substrate and forming a flip chip interconnection;
filling the vias with an electrically conductive material;
applying an electrically conductive layer onto the exposed surface of the electrically insulating material, the electrically conductive layer covering at least a portion of the dielectric side of the substrate; and
curing the electrically insulating material.

25. The method of claim 24 wherein filling the vias comprises applying a curable electrically conductive material in the vias.

26. The method of claim 25 wherein applying an electrically conductive layer comprises applying a curable conductive adhesive.

27. The method of claim 25 wherein applying an electrically conductive layer comprises applying a metal sheet.

28. The method of claim 25 wherein affixing the semiconductor die comprises providing a die having interconnection bumps affixed to an arrangement of connection sites in a first surface of thereof, and forming the flip chip interconnection comprises apposing the interconnect face of the die with interconnect sites on a first side of the package substrate and bringing the interconnect bumps into contact with a complementary arrangement of interconnect sites on the conductive trace layer under conditions of pressure and temperature that promote bonding of the bumps on the interconnect sites without melting the material of the bumps or of the interconnect sites on the conductive trace layer.

29. The method of claim 25, further comprising attaching second level interconnect solder balls onto second level interconnect sites on the conductive trace layer.

30. The method of claim 25 wherein providing the substrate comprises providing a substrate comprising a patterned electrically conductive layer and an electrically insulating layer.

31. A method for manufacturing an integrated circuit chip package, comprising
providing a substrate including a dielectric layer having first and second surfaces and a patterned electrically conductive film on the first surface, the side of the substrate having the patterned conductive film being a circuit side of the substrate, and the side of the substrate having the second surface being a dielectric side of the substrate, the substrate having vias through the dielectric layer opening on the second surface;
affixing a semiconductor die onto the circuit side of the substrate and forming a flip chip interconnection;
applying an electrically conductive material onto the dielectric side of the substrate, filling the vias and covering at least a portion of the dielectric side of the substrate; and
curing the electrically conductive material.

32. The method of claim 31 wherein applying the electrically conductive material comprises applying a curable electrically conductive adhesive.

33. The method of claim 31 wherein applying the electrically conductive material comprises applying a conductive ink.

34. The method of claim 31 wherein the substrate is provided as a single metal layer tape substrate, the method further comprising supporting the tape on a stage with at least one side of the substrate exposed for subsequent treatment.

35. The method of claim 31, further comprising affixing second level interconnect solder balls onto the circuit side of the substrate.

36. The method of claim 31 wherein the die is provided with interconnection bumps affixed to an arrangement of connection sites in a first surface of the die, and the flip chip interconnection is formed by apposing the interconnect face of the die with interconnect sites on the circuit side of the substrate and bringing the interconnect bumps into contact with a complementary arrangement of interconnect sites on the patterned conductive film under conditions of pressure and temperature that promote bonding of the bumps on the interconnect sites without melting the material of the bumps or of the interconnect sites on the conductive trace layer.

37. The method of claim 31, further comprising applying a metal sheet onto an exposed surface of the curable electrically conductive material.

38. The method of claim 37 wherein applying a metal sheet comprises applying a copper sheet.

39. The method of claim 37 wherein applying a metal sheet comprises applying an aluminum sheet.

40. The method of claim 37 wherein the electrically conductive material comprises a curable adhesive, and wherein the metal sheet is applied prior to curing the electrically conductive material.

41. A method for manufacturing an integrated circuit chip package, comprising
providing a substrate including a dielectric layer having first and second surfaces, and having an electrically insulating adhesive layer on the second surface and a patterned electrically conductive layer on the first surface, the side of the substrate having the patterned conductive layer being a “circuit side” of the substrate, and the side of the substrate having the electrically insulating adhesive layer being the “dielectric side” of the substrate, the substrate having vias through the insulating layer and the dielectric layer opening on the exposed surface of the insulating layer;
affixing a semiconductor die onto the circuit side of the substrate and forming a flip chip interconnection;
filling the vias with an electrically conductive material;
applying an electrically conductive layer onto the exposed surface of the electrically insulating material, the electrically conductive layer making electrical contact with the electrically conductive material in the vias, and thereby with selected traces in the patterned electrically conductive layer, and covering at least a portion of the dielectric side of the substrate; and
curing the electrically insulating material.
